(19) United States
(12) Patent Application Publication
(10) Pub. No.: US 2015/0070993 A1
(43) Pub. Date: Mar. 12, 2015

(54) NONVOLATILE SEMICONDUCTOR MEMORY DEVICE

(71) Applicant: KABUSHIKI KAISHA TOSHIBA, Minato-ku (JP)

(72) Inventor: Yasushi NAGADOMI, Yokohama-shi (JP)

(73) Assignee: KABUSHIKI KAISHA TOSHIBA, Minato-ku (JP)

(21) Appl. No.: 14/208,473

(22) Filed: Mar. 13, 2014

(30) Foreign Application Priority Data
Sep. 11, 2013 (JP) 2013-187896

(51) Int. Cl. G11C 29/00; G11C 16/24

(52) U.S. Cl. CPC G11C 29/00; G11C 16/24
USPC 365/185.09; 365/185.18

(57) ABSTRACT

A nonvolatile semiconductor memory device according to an embodiment comprises: a memory string including a first memory cell and a second memory cell; a first word line connected to a gate of the first memory cell; a second word line connected to a gate of the second memory cell; and a peripheral circuit configured to control a write sequence and a read sequence, the peripheral circuit, during the write sequence or the read sequence on the first memory cell, executing a first operation on the condition that a positive first pass voltage is applied to the first word line and the second word line.

### CROSS-REFERENCE TO RELATED APPLICATION

This application is based upon and claims the benefit of priority from the prior Japanese Patent Application No. 2013-187896, filed on Sep. 11, 2013, the entire contents of which are incorporated herein by reference.

### BACKGROUND

1. Field

Embodiments of the present invention relate to a nonvolatile semiconductor memory device.

2. Description of the Related Art

Currently, semiconductor memories are utilized in any number of places, from large-scale computers, personal computers, and household electrical goods to mobile phones, and the like. Receiving particular attention among these semiconductor memories is flash memory. Flash memory is utilized in many information devices such as mobile phones or digital cameras, for reasons such as it being a nonvolatile memory or it having a structure suitable for a high degree of integration, and so on.

### BRIEF DESCRIPTION OF THE DRAWINGS

FIG. 1 is an overall configuration view of a nonvolatile semiconductor memory device according to a first embodiment.

FIG. 2 is a perspective view showing a structure of a cell array of the nonvolatile semiconductor memory device according to same embodiment.

FIG. 3 is a circuit diagram of a memory string of the cell array in the nonvolatile semiconductor memory device according to same embodiment.

FIG. 4 is a perspective view showing a structure of the cell array of the nonvolatile semiconductor memory device according to same embodiment.

FIG. 5 is a circuit diagram of the memory string of the cell array in the nonvolatile semiconductor memory device according to same embodiment.

FIG. 6 is a cross-sectional view of the cell array of the nonvolatile semiconductor memory device according to same embodiment.

FIG. 7 is a cross-sectional view of the cell array of the nonvolatile semiconductor memory device according to same embodiment.

FIG. 8 is a view explaining a relationship between threshold distributions and data of a memory transistor in the nonvolatile semiconductor memory device according to same embodiment.

FIG. 9 is a timing chart of during a write sequence of the nonvolatile semiconductor memory device according to same embodiment.

FIG. 10 is a voltage waveform diagram of a word line during the write sequence of the nonvolatile semiconductor memory device according to same embodiment.

FIG. 11 is a voltage waveform diagram of the word line during the write sequence of the nonvolatile semiconductor memory device according to same embodiment.

FIG. 12 is a view explaining the write sequence of the nonvolatile semiconductor memory device according to same embodiment.

FIG. 13 is a flowchart of a read sequence of the nonvolatile semiconductor memory device according to a second embodiment.

FIG. 14 is a timing chart of during the read sequence of the nonvolatile semiconductor memory device according to same embodiment.

FIG. 15 is another timing chart of during the read sequence of the nonvolatile semiconductor memory device according to same embodiment.

FIG. 16 is a view showing a state of data during the read sequence of the nonvolatile semiconductor memory device according to same embodiment.

### DETAILED DESCRIPTION

A nonvolatile semiconductor memory device according to an embodiment comprises: a memory string including a first memory cell and a second memory cell; a first word line connected to a gate of the first memory cell; a second word line connected to a gate of the second memory cell; and a peripheral circuit configured to control a write sequence and a read sequence, the peripheral circuit, during the write sequence or the read sequence on the first memory cell, executing a first operation on the condition that a positive first pass voltage is applied to the first word line and the second word line. Here, the word “connected” of “a first word line connected to a gate of the first memory cell” and “a second word line connected to a gate of the second memory cell” means a physical connection or an electrical connection, and includes a case of being electrically connected through a current path of a transistor.

A semiconductor memory device according to embodiments will be described below with reference to the drawings.

### First Embodiment

<Overall Configuration>

First, an overall configuration of a nonvolatile semiconductor memory device according to a first embodiment will be described.

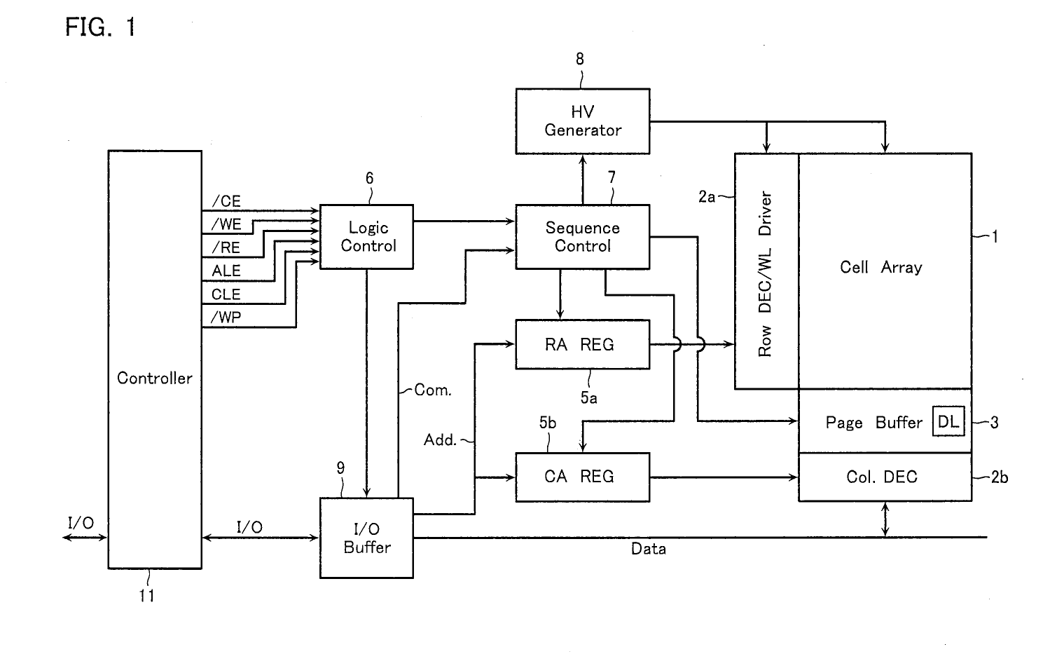

FIG. 1 is an overall configuration view of the nonvolatile semiconductor memory device according to the present embodiment.

A NAND flash memory being the nonvolatile semiconductor memory device according to the present embodiment comprises a cell array 1 and a peripheral circuit. The peripheral circuit includes a row decoder/word line driver 2a and column decoder 2b, a page buffer 3, a row address register 5a and column address register 5b, a logic control circuit 6, a sequence control circuit 7, a high voltage generating circuit 8, an I/O buffer 9, and a controller 11.

The cell array 1 has a so-called BiCS (Bit-Cost-Scalable) structure. The cell array 1 includes a plurality of memory strings similarly to a cell array of a NAND flash memory of planar structure. Each of the memory strings includes a plurality of cells connected in series. Each of the cells is configured by a transistor (hereafter, referred to as “cell transistor” or “memory cell”) having a charge accumulation layer. The cell array 1 will be described in detail later.

The row decoder/word line driver 2a drives a word line and a select gate line of the cell array 1. The page buffer 3 comprises a one-page portion of sense amplifiers and a data holding circuit, and controls read of data of the cell array 1 in page units. The page buffer 3 performs column selection sequentially by the column decoder 2b to output a one-page portion of read data to an external I/O terminal via the I/O buffer 9. Every one page of write data supplied from the I/O buffer 9 is selected by the column decoder 2b to be loaded into the page buffer 3. A row address signal and a column address signal are inputted via the I/O buffer 9 to be respectively transferred to the row decoder/word line driver 2a and the column decoder 2b. The row address register 5a holds an erase block address during an erase sequence, and holds a page address in a write sequence or a read sequence. The column address register 5b has inputted thereto a lead column address required in load of write data prior to start of the write sequence or a lead column address required in the read sequence. The column address register 5b holds an inputted column address until a write enable signal/WE or read enable signal/RE are toggled by a certain condition. The logic control circuit 6 controls input of a command or address and input/output of data based on control signals such as a chip enable signal/CE, a command enable signal CLE, an address latch enable signal ALE, the write enable signal/WE, and the read enable signal/RE. The sequence control circuit 7 receives a command from the logic control circuit 6 to control the erase sequence, the read sequence, or the write sequence. That is, the sequence control circuit 7 controls the row address register 5a, the column address register 5b, the row decoder/word line driver 2a, and so on, thereby controlling the erase sequence, the read sequence, or the write sequence. The high voltage generating circuit 8 is controlled by the sequence control circuit 7 to generate a certain voltage required in various kinds of operations. The controller 11 controls the write sequence, and so on, by conditions appropriate to a current read state, and so on. Note that as required, the page buffer 3 may comprise a data latch DL for holding open failure information, which will be described later.

<Cell Array>

Next, a specific example of the cell array 1 will be described.

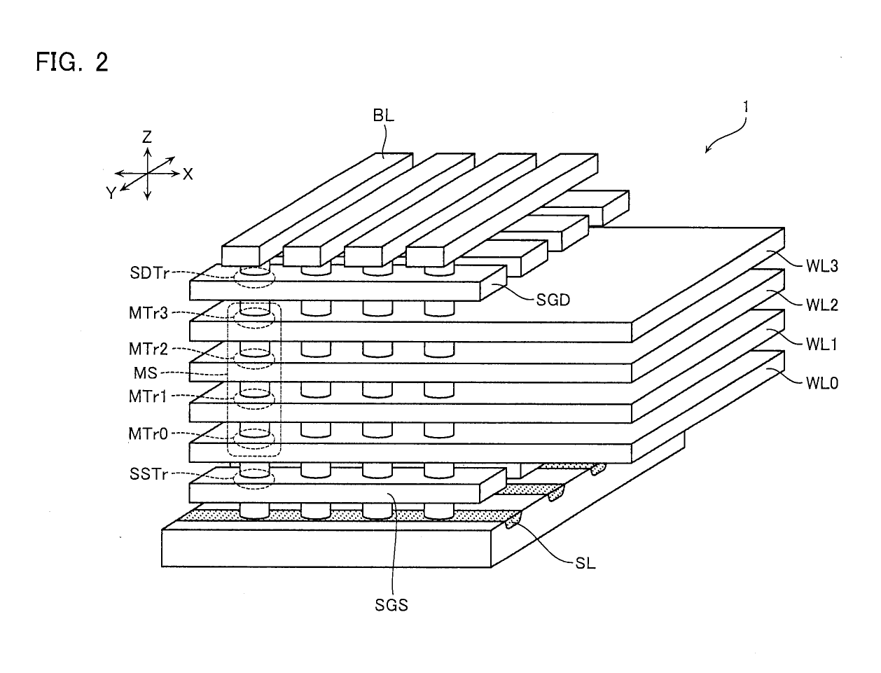

FIG. 2 is a perspective view showing a structure of the cell array of the nonvolatile semiconductor memory device according to the present embodiment. FIG. 2 shows an X direction, a Y direction, and a Z direction as three directions that intersect each other.

This cell array 1 has formed sequentially therein, on a semiconductor substrate: a plurality of source lines SL that are aligned in the Y direction and extend in the X direction; a plurality of source side select gate lines SGS that are aligned in the Y direction and extend in the X direction; a plurality of word lines WL that are planar extending in the X direction and the Y direction; a plurality of drain side select gate lines SGD that are aligned in the Y direction and extend in the X direction; and a plurality of bit lines BL that are aligned in the X direction and extend in the Y direction. Moreover, formed between each of the plurality of source lines SL and the plurality of bit lines BL is a pillar that penetrates the source side select gate line SGS, the plurality of word lines WL, and the drain side select gate line SGD. This pillar configures part of a memory string MS.

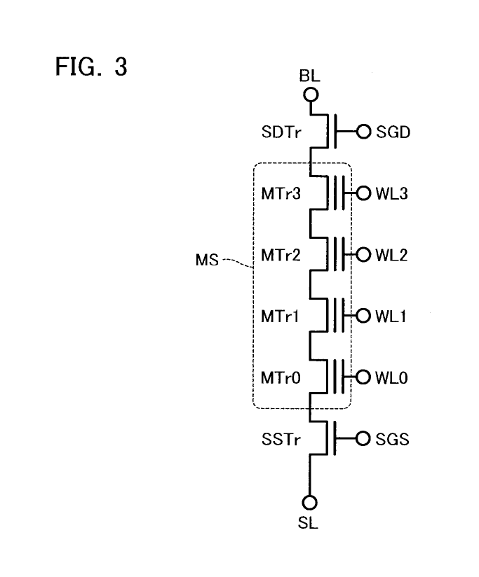

FIG. 3 is a circuit diagram of the memory string of the cell array in the nonvolatile semiconductor memory device according to the present embodiment.

FIG. 3 shows, connected in series from the source line SL to the bit line BL: a source side select transistor SSTr controlled by the source side select gate line SGS; the memory string MS; and a drain side select transistor SDTr controlled by the drain side select gate line SGD. The memory string MS includes a plurality of memory transistors MTr connected in series. Each of the memory transistors MTr is a transistor having a charge accumulation layer that has an electrically rewritable threshold voltage, and each of the memory transistors MTr has the word line WL connected to its gate electrode. Note that a structure of the memory transistor MTr will be described later.

Next, another specific example of the cell array 1 will be described.

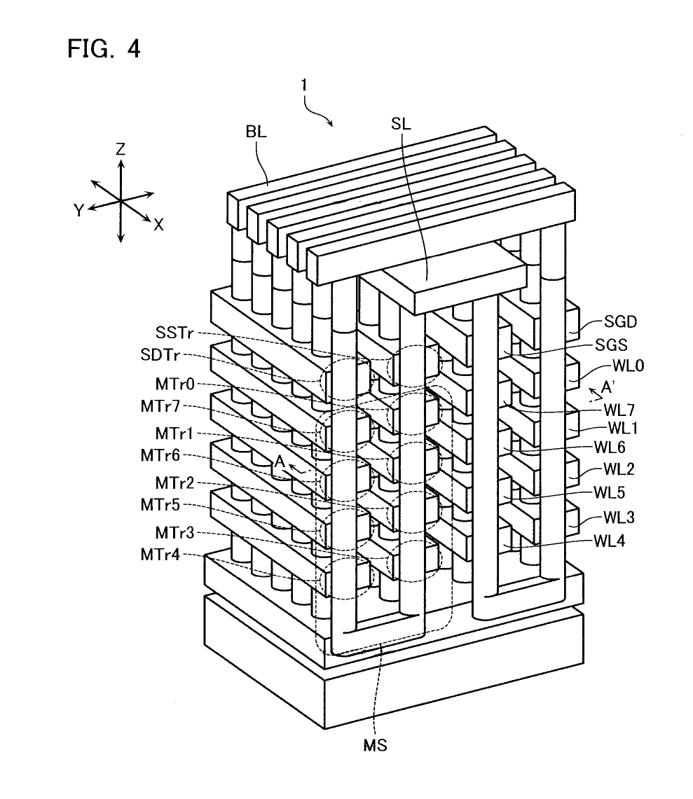

FIG. 4 is a perspective view showing a structure of the cell array of the nonvolatile semiconductor memory device according to the present embodiment. FIG. 4 shows an X direction, a Y direction, and a Z direction as three directions that intersect each other.

This cell array 1 includes, on a semiconductor substrate: a plurality of word lines WL (first lines) that are aligned in a two-dimensional matrix in the Y direction and the Z direction, and extend in the X direction; a plurality of select gate lines that are aligned in the Y direction and extend in the X direction; a plurality of source lines SL that are aligned in the Y direction and extend in the X direction; and a plurality of bit lines BL that are aligned in the X direction and extend in the Y direction. Note that the plurality of select gate lines have the source side select gate lines SGS and the drain side select gate lines SGD aligned alternately two at a time in the Y direction. Moreover, FIG. 4 shows only one source line SL. In addition, this cell array 1 includes a plurality of pillars aligned in a two-dimensional matrix in the X direction and the Y direction. Each of the pillars configures part of the memory string MS, and includes, in FIG. 4: a columnar portion CL1 that extends in the Z direction penetrating the plurality of word lines WL, and has its upper end electrically connected to the source line SL via the source side select transistor SSTr controlled by the source side select gate line SGS; a connecting portion JP that extends in the Y direction inside an interlayer insulating film on the semiconductor substrate, and has its right end connected to a lower end of the columnar portion CL1; and a columnar portion CL2 that extends in the Z direction penetrating the plurality of word lines WL, has its lower end connected to a left end of the connecting portion JP, and has its upper end electrically connected to the bit line BL via the drain side select transistor SDTr controlled by the drain side select gate line SGD. Now, a group of memory strings MS sharing the word line WL configures a memory block MB.

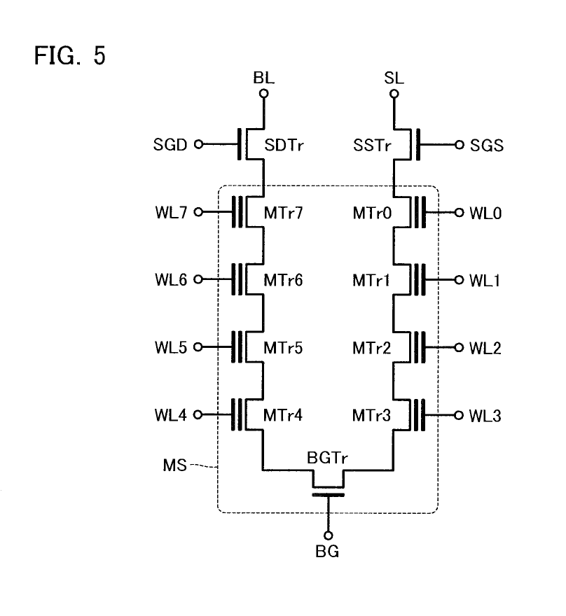

FIG. 5 is a circuit diagram of the memory string of the cell array in the nonvolatile semiconductor memory device according to the present embodiment.

The memory string MS shown in FIG. 5 is different from the memory string MS shown in FIG. 3, and includes between certain memory transistors MTr of the series-connected plurality of memory transistors MTr (in the case of FIG. 5, between the memory transistors MTr3 and MTr4) a back gate transistor BGTr controlled by a back gate line BG.

For convenience of description, the cell array 1 having a BiCS structure shown in FIG. 4 will be described as an example below. However, the present invention is not limited to this structure, and may be applied also to, for example, a BiCS structure shown in FIG. 2. Moreover, the present invention may be applied also to another structure of the cell array 1. A configuration of the cell array is described in, for example, U.S. patent application Ser. No. 12/407,403 entitled “THREE DIMENSIONAL STACKED NONVOLATILE SEMICONDUCTOR MEMORY”, filed on Mar. 19, 2009. The configuration of the cell array is also described in U.S. patent application Ser. No. 12/406,524 entitled “THREE DIMENSIONAL STACKED NONVOLATILE SEMICONDUCTOR MEMORY”, filed on Mar. 18, 2009, U.S. patent application Ser. No. 12/679,991 entitled “NON-VOLATILE SEMICONDUCTOR STORAGE DEVICE AND METHOD OF MANUFACTURING THE SAME”, filed on Mar. 25, 2010, and U.S. patent application Ser. No. 12/532,030 entitled “SEMICONDUCTOR MEMORY AND METHOD FOR MANUFACTURING SAME”, filed on Mar. 23, 2009. These patent applications are incorporated herein by reference in their entirety.

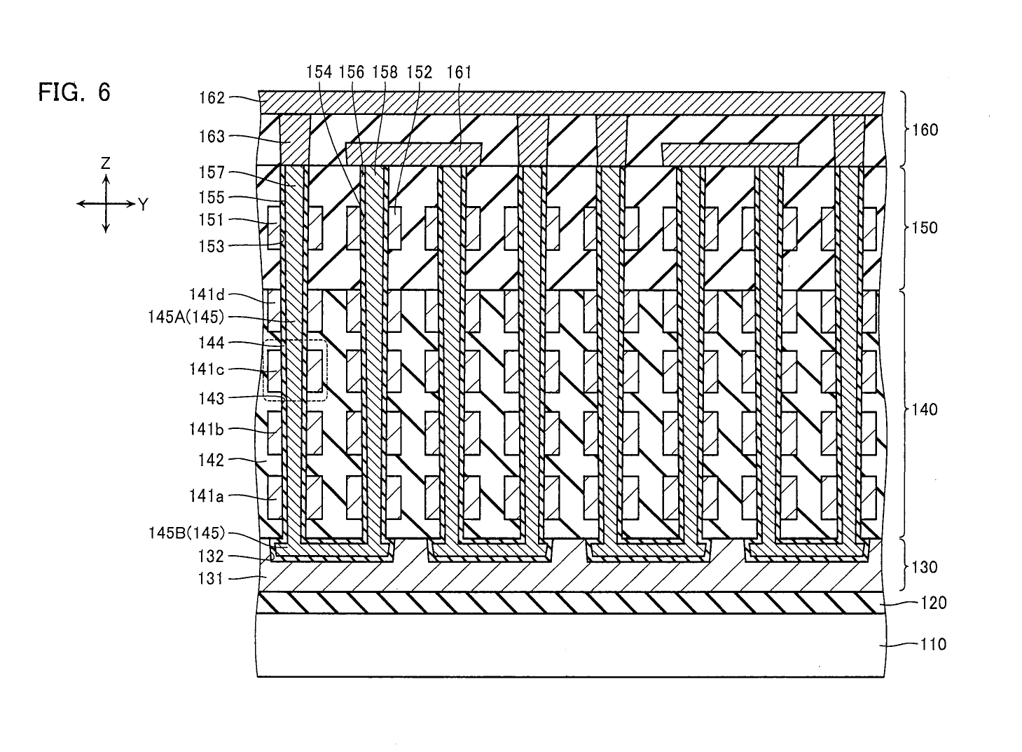

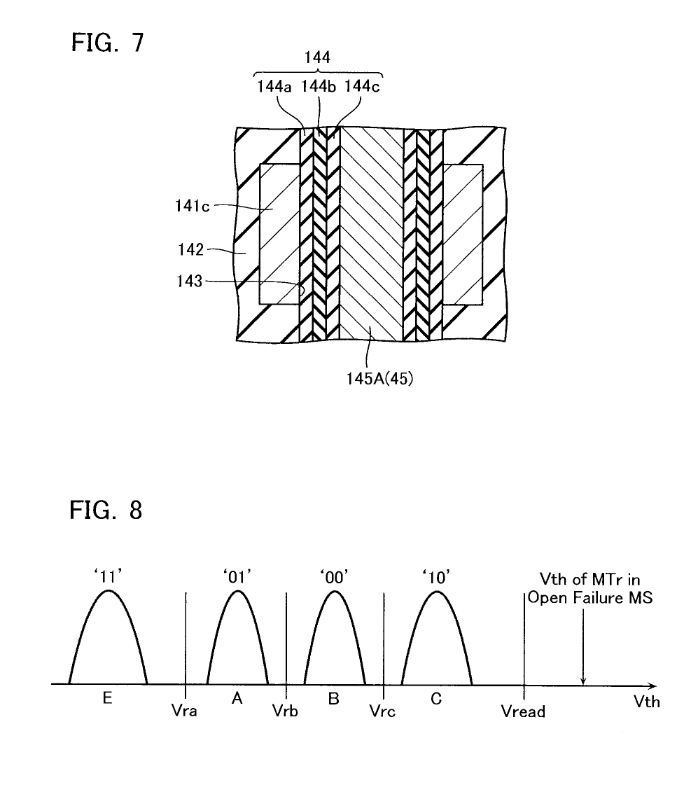

FIGS. 6 and 7 are each a cross-sectional view of the cell array in the nonvolatile semiconductor memory device according to the present embodiment. FIG. 6 is a cross-sectional view viewing the cell array of FIG. 4 in an A-A′ direction. Moreover, FIG. 7 is a cross-sectional view enlarging a region shown by the broken line of FIG. 6.

As shown in FIG. 6, the cell array 1 includes, stacked sequentially on a semiconductor substrate 110: an insulating layer 120; a back gate layer 130 that functions as the back gate transistor BTr; a memory transistor layer 140 that functions as the memory transistor MTr; a select transistor layer 150 that functions as the source side select transistor SSTr and the drain side select transistor SDTr; and a wiring line layer 160 that functions as the source line SL and the bit line BL.

The back gate layer 130 includes a back gate conductive layer 131 formed on the semiconductor substrate 110 via the insulating layer 120. The back gate conductive layer 131 functions as the back gate line BG and as a gate of the back gate transistor BTr. In addition, the back gate layer 130 includes a back gate trench 132 formed so as to dig into the back gate conductive layer 131.

The memory transistor layer 140 includes a plurality of word line conductive layers 141 formed in the Z direction while interposing an insulating layer 142. The word line conductive layer 141 functions as the word line WL and as a gate of the memory transistor MTr. In addition, the memory transistor layer 140 includes a memory hole 143 formed so as to penetrate the plurality of word line conductive layers 141 and a plurality of the insulating layers 142.

Moreover, the back gate layer 130 and the memory transistor layer 140 include a memory gate insulating layer 144 and a semiconductor layer 145. As shown in FIG. 7, the memory gate insulating layer 144 is configured by a block insulating film 144a, a charge accumulation layer 144b of the memory transistor MTr, and a tunnel insulating film 144c, in a direction from an outer side to an inner side of the memory hole 143. The semiconductor layer 145 is formed in a U shape as viewed from the X direction, and includes a pair of columnar portions 145A extending in a perpendicular direction to the semiconductor substrate 110, and a coupling portion 145B formed so as to couple lower ends of these columnar portions 145A, as viewed from the X direction. The semiconductor layer 145 functions as a body of the memory transistor MTr and the back gate transistor BTr.

The select transistor layer 150 includes a drain side conductive layer 151 and a source side conductive layer 152 that are formed in the same layer. The drain side conductive layer 151 functions as the drain side select gate line SGD and as a gate of the drain side select transistor SDTr. The source side conductive layer 152 functions as the source side select gate line SGS and as a gate of the source side select transistor SSTr. In addition, the select transistor layer 150 includes a drain side hole 153, a source side hole 154, a drain side gate insulating layer 155, a source side gate insulating layer 156, a drain side columnar semiconductor layer 157, and a source side columnar semiconductor layer 158. The drain side columnar semiconductor layer 157 functions as a body of the drain side select transistor SDTr. The source side columnar semiconductor layer 158 functions as a body of the source side select transistor SSTr.

The wiring line layer 160 includes a first wiring line layer 161, a second wiring line layer 162, and a plug layer 163. The first wiring line layer 161 functions as the source line SL. The second wiring line layer 162 functions as the bit line BL.

<Open Failure Detection of Memory String>

When employing the cell array 1 of BiCS structure, the following problem occurs.

It is conceivable that when manufacturing the cell array 1 of BiCS structure, a plurality of conductive layers and insulating films are stacked to process the memory hole 143 in one shot.

However, this memory hole 143 has a depth of as much as, for example, about 1.5 μm and has a high aspect ratio, hence processing is difficult. As a result, sometimes, the memory hole 143 stops midway and a so-called open failure occurs in the memory hole 143 (Hereafter, a memory string in which there is an open failure in the memory hole will sometimes be referred to simply as an “open failure memory string”. Moreover, a memory transistor included in an open failure memory string will sometimes be referred to simply as an “open failure memory transistor”). In this case, write and read of data to/from that open failure memory transistor MTr cannot be performed. Moreover, if many open failure memory strings MS exist in the memory block MB, relief by ECC also becomes impossible, leading to the entire memory block MB being treated as a failure.

Accordingly, in the present embodiment, a countermeasure for the open failure memory string MS is adopted during the write sequence. Note that write sequence refers to a series of processings of data write on the memory transistor MTr.

First, as a precondition to describing the write sequence of the present embodiment, a relationship between a threshold voltage and data of the memory transistor MTr will be simply described.

FIG. 8 is a view explaining a relationship between threshold distributions and data of the memory transistor in the nonvolatile semiconductor memory device according to the present embodiment. FIG. 8 shows the case of a memory transistor MTr that stores four levels of data. Note that the present embodiment is not limited to a memory transistor MTr that stores four levels of data, and may be applied also to a memory transistor MTr that stores other than four levels of data.

Set as a threshold voltage Vth of the memory transistor MTr are, in order of increasing voltage, four voltage ranges, namely level E, level A, level B, and level C. Neighboring levels are separated from each other by a certain margin. Moreover, for example, four data values, namely “11”, “01”, “00”, and “10”, correspond to level E, level A, level B, and level C. The nonvolatile semiconductor memory device stores four different data by causing the threshold voltage Vth of the memory transistor MTr to undergo transition to a desired level.

Next, as a precondition to describing the write sequence of the present embodiment, a read operation from the memory transistor MTr will be simply described. Note that this read operation is employed as an “ordinary read operation” in step S201 of a read sequence shown in FIG. 13 which will be described later.

The read operation is executed targeting a selected memory transistor MTr of a selected memory string MS of a selected memory block MB. First, the page buffer 3 charges the bit line BL to “H” level, and the row decoder/word line driver 2a applies a reference voltage Vrf to a selected word line WL and a read voltage Vread to an unselected word line WL. Now, the reference voltage Vrf is, for example, any of a voltage Vra between level E and level A, a voltage Vrb between level A and level B, and a voltage Vrc between level B and level C, shown in FIG. 8. Moreover, the read voltage Vread is a voltage which is higher than that of the highest level C. Therefore, the unselected memory transistors MTr all attain an on state regardless of what data the unselected memory transistor MTr itself is storing. In addition, the row decoder/word line driver 2a applies to the source side select gate line SGS and the drain side select gate line SGD a select gate voltage Vsg sufficient for the source side select transistor SSTr and the drain side select transistor SDTr to be turned on. In the above bias state, if the reference voltage Vrf of the selected word line WL is larger than the threshold voltage Vth of the selected memory transistor MTr, then the selected memory string MS conducts whereby a current flows from the bit line BL to the source line SL, and the bit line BL lowers to “L” level. On the other hand, if the reference voltage Vrf of the selected word line WL is smaller than the threshold voltage Vth of the selected memory transistor MTr, then a current does not flow from the bit line BL, and the bit line BL is maintained unchanged at “H” level.

Then, the current flowing in this bit line BL is detected by the sense amplifier included in the page buffer 3, whereby data of the selected memory transistor MTr is determined. Specifically, when reading data of a lower bit of the selected memory transistor MTr, the selected memory string MS is put in the above-described bias state, and then the row decoder/word line driver 2a applies the reference voltage Vrf=Vrb to the selected word line WL. If, as a result, the selected memory transistor MTr is turned on and a current flows in the bit line BL, then the threshold voltage Vth of that selected memory transistor MTr is at level E or level A, hence the lower bit is understood to be “1”.

Next, the write sequence of the present embodiment will be described.

The write sequence according to the present embodiment includes two operations, that is, a memory hole detection operation (first operation) that detects presence/absence of an open failure of a memory hole in the memory block MB, and a write operation that writes data to the memory transistor MTr.

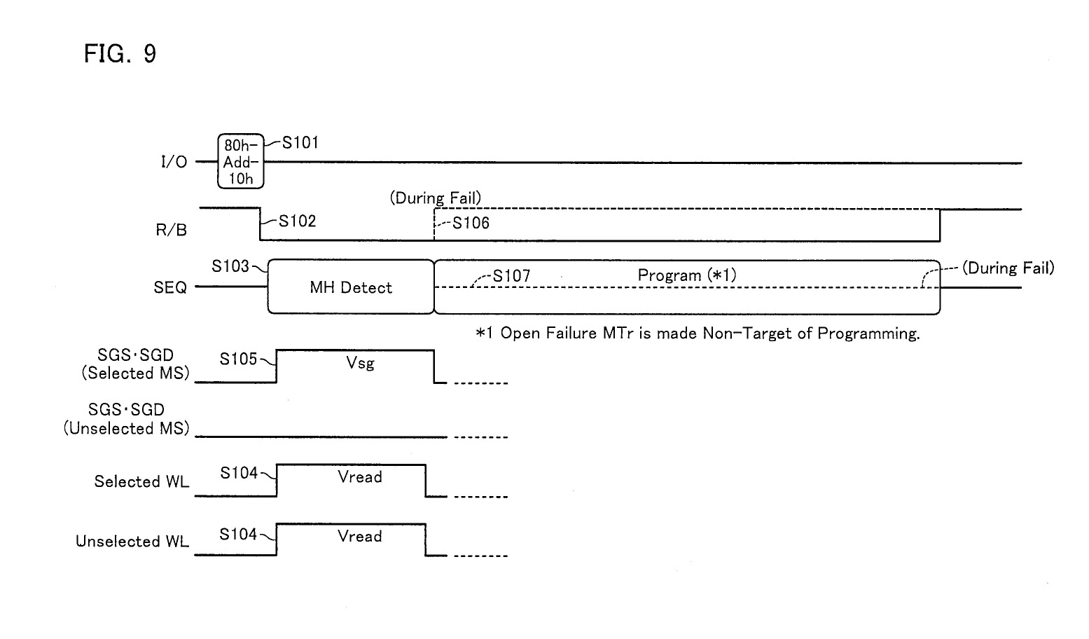

FIG. 9 is a timing chart of during the write sequence of the nonvolatile semiconductor memory device according to the present embodiment. Note that in FIG. 9, a timing chart of the source side select gate line SGS, and so on, related to the write sequence, is abbreviated.

First, when an instruction of data write is inputted from the controller 11 via I/O (this instruction is, for example, a command, such as “80h-Add-10h” of FIG. 9) (step S101), then a ready/busy signal R/B attains “L” level, in other words, a busy state (step S102). As a result, the sequence control circuit 7 shifts to the memory hole detection operation (“MH Detect” of FIG. 9) (step S103).

When the memory hole detection operation is entered, the page buffer 3 charges the bit line BL to “H” level, and the row decoder/word line driver 2a applies the read voltage Vread to all of the word lines WL, including selected/unselected word lines WL (step S104). Then, the row decoder/word line driver 2a applies the select gate voltage Vsg to the source side select gate line SGS and the drain side select gate line SGD of the selected memory string MS (step S105). At this time, the source side select gate line SGS and the drain side select gate line SGD of the unselected memory string MS are maintained unchanged at a ground voltage Vss.

If it is assumed there is an open failure in the selected memory string MS, then the selected memory string MS never conducts even if the read voltage Vread is applied to the selected word line WL. This is because the memory hole of the selected memory string MS is an open failure and a current does not flow from the bit line BL to the source line SL. Since the selected memory string MS does not conduct regardless of a voltage applied to the selected word line WL, then as shown in FIG. 8, this is equivalent to the selected memory string having a threshold voltage Vth sufficiently larger compared to the read voltage Vread. A current does not flow from the bit line BL to the source line SL, and the bit line BL is maintained unchanged at “H” level. Accordingly, in this case, the page buffer 3 determines there is an open failure in the selected memory string MS.

On the other hand, if it is assumed there is not an open failure in the selected memory string MS, then the read voltage Vread which is higher than the highest level C is applied to the gates of all of the memory transistors MTr, hence all of the memory transistors MTr attain an on state regardless of what data the memory transistor MTr itself is storing. In this case, the selected memory string MS conducts, hence a current flows from the bit line BL to the source line SL, and the bit line BL lowers to “L” level. In this case, the page buffer 3 determines there is at least not an open failure in this selected memory string MS.

The memory hole detection operation of the above kind is performed on all of the memory strings MS in the memory block. Subsequently, when, for example, there is/are a certain number or more of the open failure memory strings MS in the memory block, then as shown by the dotted line of FIG. 9, the ready/busy signal R/B is set to “H” level (step S106), a status of write failure is returned to the controller 11, and the write sequence is finished (step S107). On the other hand, when there was/were not more than a certain number or more of the open failure memory strings MS in the memory block, the write operation is performed (“Program” of FIG. 9). Settable as this certain number is, for example, the number correctable by ECC. The certain number is not limited to the number correctable by ECC, and may be set arbitrarily.

Here, reference will be made to the case where the write operation includes a verify operation (read operation) that verifies whether write of data has been completed or not.

In such a case, if there is an open failure memory string MS, then the following problem occurs. In other words, since write of data cannot be performed in the open failure memory transistor MTr, then, depending on the data it is desired to write, verify cannot be passed. This case results in programming on the memory transistor MTr being repeated, and processing of the write sequence being delayed.

Accordingly, if it is desired to solve such a problem, then the write operation is processed making the open failure memory transistor MTr non-target of programming. For example, in the verify operation (read operation), when the open failure memory transistor MTr maybe regarded as storing a data value “1”, then, regardless of input data, the open failure memory transistor MTr is made non-target of programming (programming prohibited), after which the verify operation is processed assuming write data was “1”. In this way, the open failure memory transistor MTr can immediately pass verify, hence a wasted verify operation on the open failure memory transistor MTr can be reduced. Note that in the case of this method, an error is sometimes also included in stored data, but in this case all that is required is to perform error correction by the likes of an external ECC system.

Next, reference will be made also to a voltage application method on the word line WL during switching from the memory hole detection operation to the write operation.

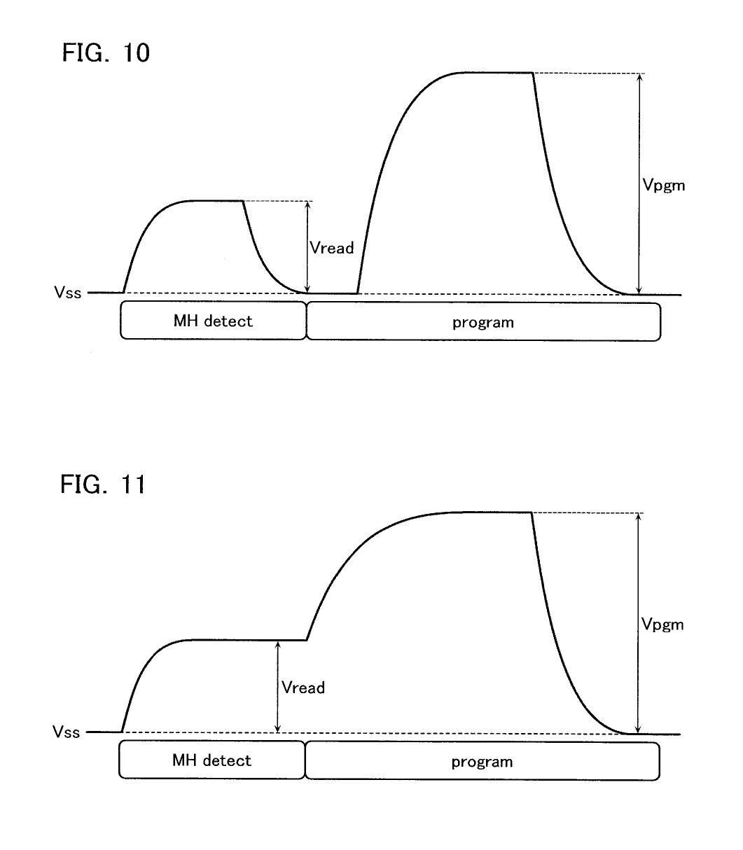

FIGS. 10 and 11 are each a voltage waveform diagram of the word line during the write sequence of the nonvolatile semiconductor memory device according to the present embodiment.

In each of the examples of FIGS. 10 and 11, the read voltage Vread is applied to the word line WL during the memory hole detection operation, and a programming voltage Vpgm is applied to the word line WL during the write operation. However, during switching from the memory hole detection operation to the write operation, whereas in the case of FIG. 10, a voltage of the word line WL is first dropped to the ground voltage Vss before being raised to the programming voltage Vpgm, in the case of FIG. 11, the voltage of the word line WL is raised directly from the read voltage Vread to the programming voltage Vpgm without being dropped to the ground voltage Vss.

The voltage application methods on the word line WL in the examples of FIGS. 10 and 11 can each be applied to the write sequence according to the present embodiment. However, when considering reduction of processing time of the write sequence, the example of FIG. 11 is more advantageous.

Note that in the memory hole detection operation, the number of open failure memory strings MS may be counted, or only a non-write and open failure memory string MS, in other words, a memory string MS whose status is read failure, may be detected.

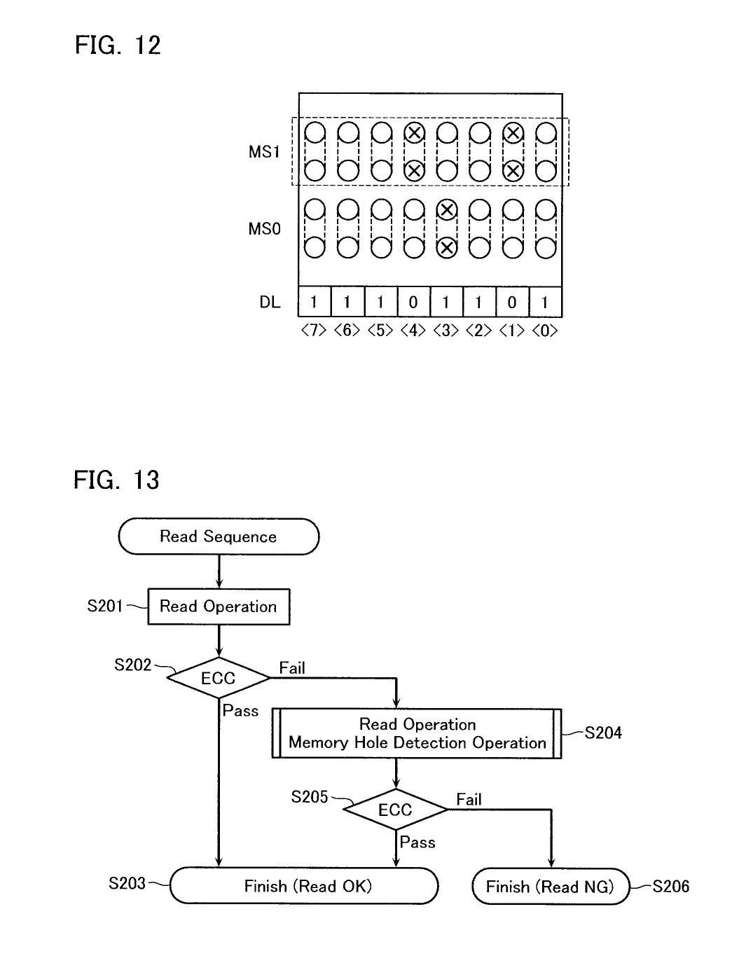

In addition, an open failure detection result (hereafter, referred to as “memory hole data”) may be configured to, for example, be held in a data latch DL provided in the likes of the page buffer 3 and be readable from the controller 11. FIG. 12 is a view showing a plan view of the memory block as seen from the Z direction and contents of the data latch DL, and indicates a place of open failure of the memory string MS by an x mark. For example, as shown in FIG. 12, when there is an open failure in memory strings MS1<1> and MS1<4> of the memory block, data latches DL<1> and DL<4> of the data latches DL that store the memory hole data of the memory strings MS1 have stored therein data “0” indicating there is an open failure, and data latches DL<0>, and so on, corresponding to the other normal memory strings MS1 have stored therein data “1” indicating there is not an open failure. If data is stored in the data latches DL in this way and, for example, data of the data latches DL<0> to DL<7> is transferred in advance to the controller 11, the controller 11 can determine which of the bits is an open failure. As a result, when writing data from external, a bit where an open failure is indicated can be skipped, an address designated, and the write sequence executed.

In the case of a cell array of BiCS structure, lithography of a critical layer performed in each layer is unnecessary, hence the cell array of BiCS structure is advantageous over a conventional stacked-structure cell array in terms of cost. On the other hand, in the case of the cell array of BiCS structure, it has been a problem that it is required to form a memory hole having a depth of about 1.5 μm in the stacking direction, and an open failure occurs frequently in the memory hole.

Regarding this frequent occurrence of open failure, in the present embodiment, detection of open failure is performed before the write operation, hence write to an open failure memory string can be avoided. As a result, data reliability can be improved even when employing a cell array of BiCS structure.

### Second Embodiment

In the first embodiment, a countermeasure for the open failure memory string MS during the write sequence was described, but in a second embodiment, a countermeasure for the open failure memory string MS during the read sequence will be described.

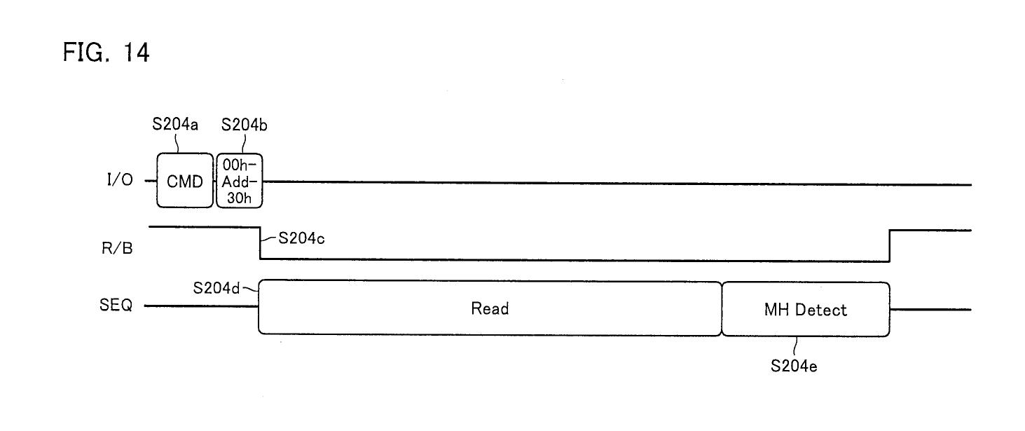

FIG. 13 is a flowchart of the read sequence of a nonvolatile semiconductor memory device according to the second embodiment. Moreover, FIG. 14 is a timing chart of during same read sequence.

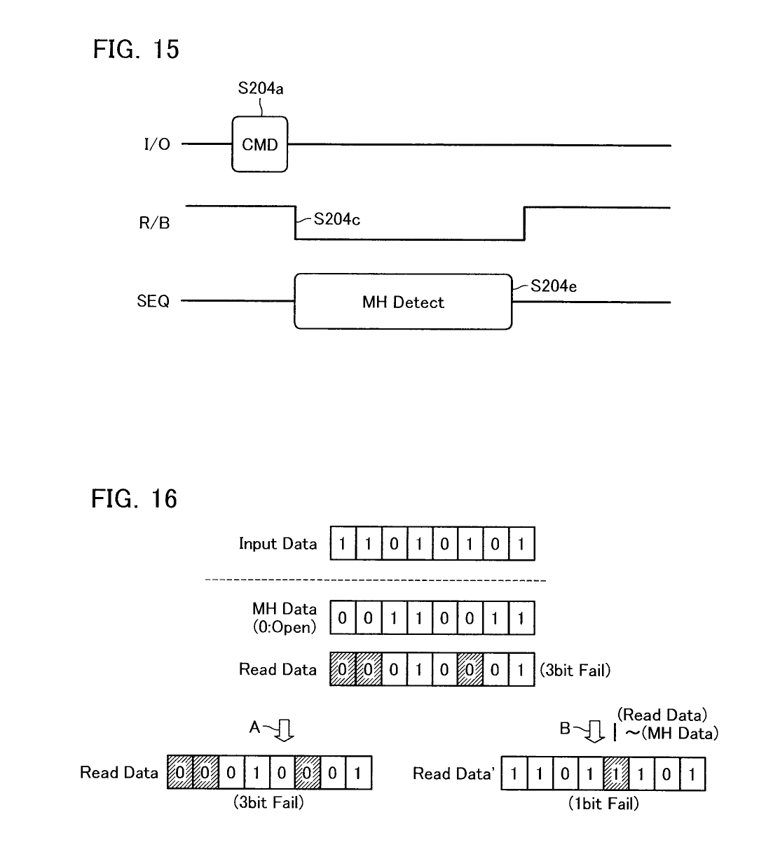

In the read sequence of the present embodiment, first, the sequence control circuit 7 executes the ordinary read operation described in the first embodiment (step S201). Next, the sequence control circuit 7 executes ECC on read data (step S202). Now, if an error of the read data is in a range of correction capability of ECC and error correction by ECC has succeeded, then the read sequence is finished adopting that corrected data as output data (step S203). On the other hand, if an error of the read data has exceeded the range of correction capability of ECC, then processing is shifted to step S204. In step S204, after execution of the ordinary read operation, the sequence control circuit 7 executes the memory hole detection operation similar to that of the first embodiment. Now, FIG. 14 configures a timing chart related to step S204. As shown in FIG. 14, in step S204, in order to distinguish from the ordinary read operation, first, a special instruction is inputted from the controller 11 via I/O (this instruction is, for example, a command, such as “CMD” of FIG. 14) (step S204a), then an ordinary instruction of data read (for example, “00h-Add-30h” of FIG. 14) is inputted (step S204b). That being done, the ready/busy signal R/B attains “L” level, in other words, a busy state (step S204c). As a result, step S204 sequentially executes the read operation (“Read” of FIG. 14) and the memory hole detection operation. Then, the column decoder 2b and the page buffer 3 perform necessary computational processing on the read data. Specific content of this computational processing will be described later. Note that in the case of FIG. 14, the read operation is executed in step S204d, but if a result of the read operation in step S201 is, for example, held in the likes of the data latch DL provided in the page buffer 3, then as shown in FIG. 15, the read operation of step S204d may also be omitted.

Subsequently, ECC is executed on the read data that has undergone the computational processing in step S204 (step S205). Now, in the case where error correction by ECC has succeeded, the read sequence is finished adopting the post-computational processing data as output data (step S203). On the other hand, in the case where error correction by ECC has been unable to be performed, the read sequence is finished as a read failure (step S206). Note that correction capability may be changed between ECC in step S204 and ECC in step S202.

Next, the computational processing in step S204 will be described.

FIG. 16 is a view showing a state of data during the read sequence of the nonvolatile semiconductor memory device according to the present embodiment.

Now, FIG. 16 presupposes the case where input data is “11010101”, and the memory hole data (“MH Data” of FIG. 16) is “00110011”. “1” in the input data is data corresponding to the threshold voltage distribution Vth being low level, and “0” in the input data is data corresponding to the threshold voltage Vth being high level. Therefore, the memory transistor MTr of the open failure memory string MS is always in a state where data “0” is stored. In addition, “1” in the memory hole data indicates a normal memory string MS, and “0” in the memory hole data indicates an open failure memory string MS.

In the case shown in FIG. 16, since the number of open failure memory strings MS is four, there are at most four bits of errors of the read data due to open failure. Of bits of the input data affected by open failure, the fourth lowest bit is “0”, hence, in effect, this one bit has correct data written thereto. This means that ultimately, there are three bits of errors included in the read data. In the case of A in FIG. 16, the read data including this three-bit error (first read data) is processed as is by ECC. On the other hand, in the case of B in FIG. 16, a logical sum (OR) of the read data and a negation (NOT) of the memory hole data is taken. In this case, a bit of the read data corresponding to “0” data of the memory hole data is inverted to “1”. As a result, the number of error bits included in the post-computational processing read data (“Read Data′” of FIG. 16) can be suppressed to one bit. Moreover, the read data including this one-bit error (second read data) is processed by ECC.

Now, if, for example, error correction capability of ECC was two bits, then in the case of read data generated by the processing of A in FIG. 16, error correction cannot be performed, but in the case of read data generated by the processing of B in FIG. 16, error correction becomes possible. As a result of inverting the bits of the read data affected by open failure based on the memory hole data in this way, it is made possible, by either of generating procedures A and B in FIG. 16, to obtain read data that has a number of error bits which is only half or less than half of the maximum number of error bits generated by open failure. In other words, if the computational processing shown in FIG. 16 is performed, it becomes possible to correct an amount of errors due to open failure which is up to twice the error correction capability of ECC.

As described above, the present embodiment enables an apparent effect of open failure to be reduced by half, hence enables reliability of data to be improved. In addition, products having an amount of open failures up to twice the conventional tolerance number of open failures at shipment can be made shipment-target products, hence leading also to yield improvement.

[Other]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory string including a first memory cell and a second memory cell;
a first word line connected to a gate of the first memory cell;
a second word line connected to a gate of the second memory cell; and
a peripheral circuit configured to control a write sequence and a read sequence,
the peripheral circuit, during the write sequence or the read sequence on the first memory cell, executing a first operation on the condition that a positive first pass voltage is applied to the first word line and the second word line.

2. The nonvolatile semiconductor memory device according to claim 1, wherein
the peripheral circuit includes a first region that be capable of holding a result of the first operation.

3. The nonvolatile semiconductor memory device according to claim 1,
comprising a plurality of the memory strings, wherein
the write sequence includes the first operation and a write operation on the condition that a write voltage is applied to the first word line after the first operation, and
the peripheral circuit, when a first number or more of the memory strings is/are judged to be a failure by the first operation, finishes the write sequence without executing the write operation.

4. The nonvolatile semiconductor memory device according to claim 1, wherein
the peripheral circuit, during the read sequence, when, as a result of the first operation, there is the memory string judged to be a failure, inverts first data read from the memory cell selected from said memory string judged to be a failure, to generate second data.

5. The nonvolatile semiconductor memory device according to claim 4, wherein
the peripheral circuit, during the read sequence, executes a second operation that corrects the first data, and in the case that the second operation has failed, executes a third operation that corrects the second data.

6. The nonvolatile semiconductor memory device according to claim 1, wherein
the write sequence includes the first operation and a write operation on the condition that a write voltage is applied to the first word line after the first operation, and
the peripheral circuit, during switching from the first operation to the write operation of the write sequence on the first memory cell, changes a voltage applied to the first word line from the first pass voltage directly to the write voltage.

7. The nonvolatile semiconductor memory device according to claim 1, wherein
the write sequence includes the first operation and a write operation on the condition that a write voltage is applied to the first word line after the first operation, and
the peripheral circuit, during switching from the first operation to the write operation of the write sequence on the first memory cell, changes a voltage applied to the first word line to the write voltage after once changing the voltage applied to the first word line from the first pass voltage to a ground voltage.

8. The nonvolatile semiconductor memory device according to claim 1, wherein
the peripheral circuit, during the write sequence, when, as a result of the first operation, there is the memory string judged to be a failure, prohibits write of data to the memory cell of said memory string judged to be a failure.

9. A nonvolatile semiconductor memory device, comprising:
a semiconductor substrate;
a memory string that includes a first memory cell and a second memory cell and extends perpendicularly to the semiconductor substrate;
a first word line connected to agate of the first memory cell;
a second word line connected to a gate of the second memory cell; and
a peripheral circuit configured to control a write sequence and a read sequence,
the peripheral circuit, during the write sequence or the read sequence on the first memory cell, executing a first operation on the condition that a positive first pass voltage is applied to the first word line and the second word line.

10. The nonvolatile semiconductor memory device according to claim 9, wherein
the peripheral circuit includes a first region that be capable of holding a result of the first operation.

11. The nonvolatile semiconductor memory device according to claim 9,
comprising a plurality of the memory strings, wherein
the write sequence includes the first operation and a write operation on the condition that a write voltage is applied to the first word line after the first operation, and
the peripheral circuit, when a first number or more of the memory strings is/are judged to be a failure by the first operation, finishes the write sequence without executing the write operation.

12. The nonvolatile semiconductor memory device according to claim 9, wherein
the peripheral circuit, during the read sequence, when, as a result of the first operation, there is the memory string judged to be a failure, inverts first data read from the memory cell selected from said memory string judged to be a failure, to generate second data.

13. The nonvolatile semiconductor memory device according to claim 12, wherein
the peripheral circuit, during the read sequence, executes a second operation that corrects the first data, and in the case that the second operation has failed, executes a third operation that corrects the second data.

14. The nonvolatile semiconductor memory device according to claim 9, wherein
the write sequence includes the first operation and a write operation on the condition that a write voltage is applied to the first word line after the first operation, and
the peripheral circuit, during switching from the first operation to the write operation of the write sequence on the first memory cell, changes a voltage applied to the first word line to the write voltage after once changing the voltage applied to the first word line from the first pass voltage to a ground voltage.

15. The nonvolatile semiconductor memory device according to claim 9, wherein
the peripheral circuit, during the write sequence, when, as a result of the first operation, there is the memory string judged to be a failure, prohibits write of data to the memory cell of said memory string judged to be a failure.

16. A nonvolatile semiconductor memory device, comprising:
a memory string including a first memory cell and a second memory cell;
a first word line connected to a gate of the first memory cell;
a second word line connected to a gate of the second memory cell; and
a peripheral circuit configured to control a write sequence and a read sequence,
the memory cell storing different data by a plurality of threshold voltage distributions, and
the peripheral circuit, during the write sequence or the read sequence on the first memory cell, executing a first operation on the condition that a first pass voltage applied to the first word line and the second word line is higher than the plurality of threshold voltage distributions.

17. The nonvolatile semiconductor memory device according to claim 16, wherein
the peripheral circuit includes a first region that be capable of holding a result of the first operation.

18. The nonvolatile semiconductor memory device according to claim 16,
comprising a plurality of the memory strings, wherein
the write sequence includes the first operation and a write operation on the condition that a write voltage is applied to the first word line after the first operation, and
the peripheral circuit, when a first number or more of the memory strings is/are judged to be a failure by the first operation, finishes the write sequence without executing the write operation.

19. The nonvolatile semiconductor memory device according to claim 16, wherein
the peripheral circuit, during the read sequence, when, as a result of the first operation, there is the memory string judged to be a failure, inverts first data read from the memory cell selected from said memory string judged to be a failure, to generate second data.

20. The nonvolatile semiconductor memory device according to claim 19, wherein
the peripheral circuit, during the read sequence, executes a second operation that corrects the first data, and in the case that the second operation has failed, executes a third operation that corrects the second data.
